(19) United States
(12) Patent Application Publication
(10) Pub. No.: US 2023/0369052 A1
(43) Pub. Date: Nov. 16, 2023

(54) NANO-SCALE LITHOGRAPHY METHOD

(71) Applicant: BILKENT UNIVERSITESI (UNAM) ULUSAL NANOTEKNOLOJI ARASTIRMA MERKEZI, Ankara (TR)

(72) Inventors: Onur TOKEL, Ankara (TR); Rana Asgari SABET, Ankara (TR); Aqiq ISHRAQ, Ankara (TR)

(73) Assignee: BILKENT UNIVERSITESI (UNAM) ULUSAL NANOTEKNOLOJI ARASTIRMA MERKEZI, Ankara (TR)

(21) Appl. No.: 17/840,023

(22) Filed: Jun. 14, 2022

(30) Foreign Application Priority Data
May 13, 2022 (TR) 2022/007784

(51) Int. Cl. H01L 21/268; G02B 27/09; G02B 27/28; G03F 7/20

(52) U.S. Cl. CPC H01L 21/268; G02B 27/0955; G02B 27/286; G02B 27/0927; G03F 7/70525; G03F 7/7055; G03F 7/704

(57) ABSTRACT

The present invention relates to a method (100) which enables to fabricate one-dimensionally (linear) and two-dimensionally (planar)-confined micro/nano-structures at a desired position and depth inside a silicon chip, as embedded (buried) inside the chip and without damaging the chip surface, by means of spatially-structured laser beams.

### TECHNICAL FIELD

The present invention relates to a method which enables to fabricate one-dimensionally (linear) and two-dimensionally (planar)-confined micro/nano-structures at a desired position and depth inside a silicon chip, as embedded (buried) inside the chip and without damaging the chip surface, by means of spatially-structured laser beams.

### BACKGROUND OF THE INVENTION

Today, circuit boards used in electronic and photonic technologies are produced by using silicon chips. For using silicon chips as a circuit board (chip), nano-scale production is carried out on the chip surface by means of conventional lithography techniques. The prior art of silicon in-chip (in-chip volume) laser-structuring proves that it is possible to overcome the limitations of energy delivery at the micro-scale by using nanosecond pulses. A promising aspect for smaller critical dimensions is to exploit spatially-structured laser beams. However, until now, attempts to overcome the energy delivery for volumetric lithography based on spatially-structured laser beams have been unsuccessful. Consequently, there is no known in-chip nano-scale lithography technique which is created without altering the chip surface inside the silicon. It will be possible to obtain complex architectures and advanced devices by creating lithography as embedded inside the silicon in-chip volume.

Therefore, there is a need for a method which enables to fabricate structures of 1-μm size and smaller scales, as embedded inside the silicon-based chip, without damaging the chip surface and also to reduce the fabrication resolution between the in-chip lithographic structures below 1-μm.

The International patent document no. WO03079416, an application in the state of the art, discloses a method which enables laser-assisted imprinting into the surface of a solid substrate. The said method can directly imprint a desired pattern on the top surface of a wafer by the steps of providing a mold having a patterned surface to imprint the desired pattern, irradiating the substrate surface with radiation to soften or liquefy the molding surface, and disposing the molding surface adjacent or against the substrate surface. The substrate can be any one of a wide variety of solid materials such as semiconductors, metals, or polymers. The substrate is silicon, the laser is a UV laser, and the mold is transparent to the UV radiation to permit irradiation of the silicon work piece through the transparent mold. With this method, imprinting on-chip large area patterns with sub-10 nanometer resolution in sub-250 nanosecond processing time is performed. The method can also be used with a flat molding surface to planarize the substrate.

### SUMMARY OF THE INVENTION

An objective of the present invention is to realize a method which enables to fabricate one-dimensionally (linear) and two-dimensionally (planar)-confined micro/nano-structures at a desired position and depth inside a silicon chip, as embedded inside the chip and without damaging the chip surface, by means of spatially-structured laser beams.

Another objective of the invention is to realize a method which enables to reduce the fabrication resolution between the in-chip lithographic structures below 1-μm.

Another objective of the present invention is to realize a method which enables to perform nano-scale and in-chip lithography with high control and repeatability by focusing the laser pulses, that operate in a wavelength range wherein the silicon chip is transparent, into the chip upon patterning them by means of a spatial light modulator.

### DETAILED DESCRIPTION OF THE INVENTION

“A Nano-Scale Lithography Method” realized to fulfil the objectives of the present invention is shown in the figures attached, in which:

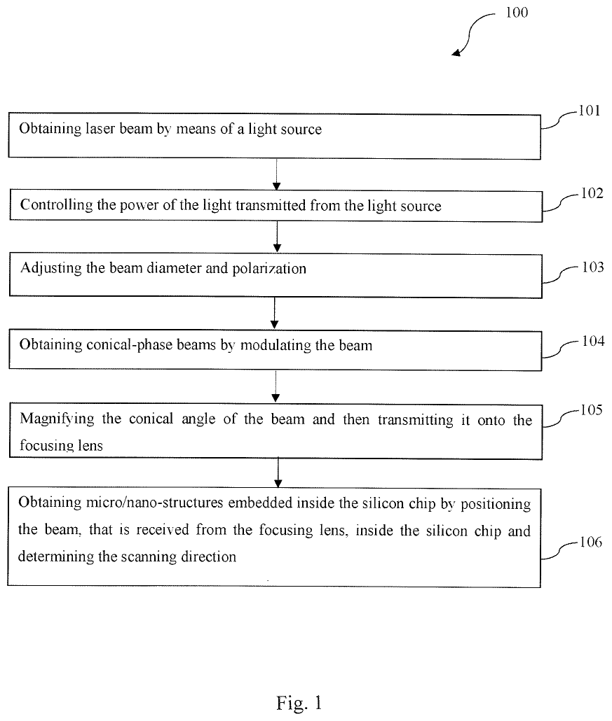

FIG. 1 is a flow chart of the inventive method.

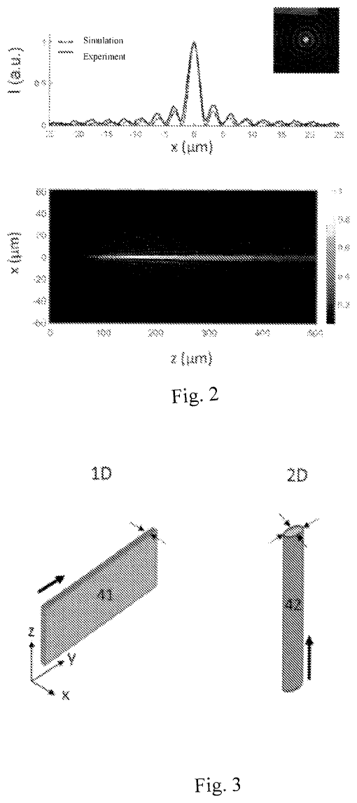

FIG. 2 shows a representative beam profile created by reflecting a Gaussian beam of 4 mm diameter from the spatial light modulator with a positive phase sign and r₀=10×20 μm.

FIG. 3 is a view of direction of 1-dimensionally (1D) and 2-dimensionally (2D) laser writing inside the silicon chip.

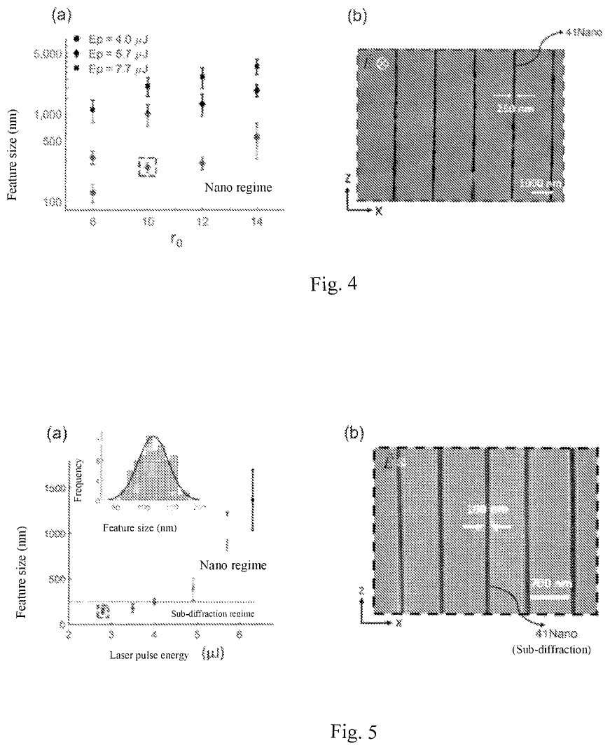

FIG. 4 shows (a) the feature change graph of micro (41Micro) and nano (41Nano)-scale structures fabricated by changing the ro parameter and (b) the SEM images of the x-z surface of the silicon chip.

FIG. 5 shows (a) the pulse energy and feature size graph of the 1D-confined structures obtained in the sub-diffraction regime and (b) the SEM images of the x-z surface of the silicon chip. r₀=10.

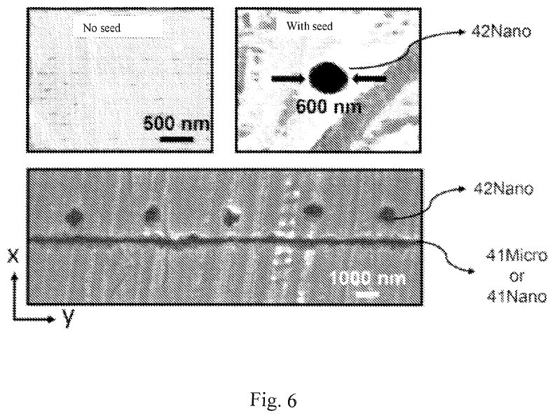

FIG. 6 shows the SEM image of x-y surface of 1D- and 2D-confined micro/nano structures.

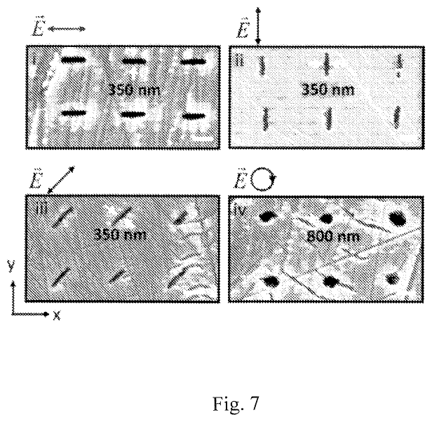

FIG. 7 shows SEM images on the x-y surface of the (42Nano) structure arrays created with four different polarizations, by using the same writing parameters.

20 The components illustrated in the figure are individually numbered, where the numbers refer to the following:
100. Method
41. Embedded structures with one-dimensionally (1D)-confined laser writing
42. Embedded structures with two-dimensionally (2D)-confined laser writing
41Micro. One-dimensionally (1D)-confined sub-surface micro structures
42Micro. Two-dimensionally (2D)-confined sub-surface micro structures
41Nano. One-dimensionally (1D)-confined sub-surface nano structures
42Nano. Two-dimensionally (2D)-confined sub-surface nano structures

The inventive method (100) which enables to fabricate one-dimensionally (linear) and two-dimensionally (planar)-confined micro/nano-structures at a desired position and depth inside a silicon chip, as embedded inside the chip and without damaging the chip surface, by means of spatially-structured laser beams comprises the following steps:
obtaining laser beam by means of a light source (101);
controlling the power of the light transmitted from the light source (102);
adjusting the beam diameter and polarization (103);
obtaining conical-phase beams by modulating the beam (104);
magnifying the conical angle of the beam and then transmitting it onto the focusing lens (105); and
obtaining micro/nano-structures embedded inside the silicon chip by positioning the beam, that is received from the focusing lens, inside the silicon chip and determining the scanning direction (106).

At the step of laser beam by means of a light source (101) of the inventive method (100), the light source used is laser and it emits Gaussian pulses with a width of 1-30 nanoseconds and a repetition rate of 1-300 kHz. In another embodiment of the invention, lengths o single laser pulse or longer laser pulse can be used with high pulse energy. Beam is obtained in the wavelength range wherein the silicon chip is transparent, by means of light source. In a preferred embodiment of the invention, a beam is used in a wavelength of 1.55 μm wherein the silicon chip is transparent.

At the step of controlling the power of the light transmitted from the light source (102) of the inventive method (100), power of the light transmitted from the light source is controlled by means of a power controller that can be a quarter-wave plate (QWP) and half-wave plate (HWP), neutral density filter, or any power adjusting component. Power controller enables to change the laser pulse energy for fixed pulse width and repetition rate.

At the step of adjusting the beam diameter and polarization (103) of the inventive method (100), a telescope system consisting of two lenses or a beam expander is used for adjustment of beam diameter. For polarization, a polarizing-beam-splitter (PBS) or wave plate is used to obtain s-polarization, p-polarization. In another embodiment of the invention, any linear combination of s- and p-polarizations (circular or elliptical polarization) is used.

At the step of obtaining conical-phase beams by modulating the beam (104) of the inventive method (100), the beam with adjusted diameter and polarization—namely the Gaussian beam—is transmitted to a physical or virtual digital device which modulates the Gaussian beam. In an embodiment of the invention, an Axicon is a typical physical optics device that can be used for modulating the beam shape, most commonly to the zeroth-order of the first kind Bessel function. Whereas in its digital application, it enables to perform light modulation by applying computer-generated phase profiles, by using a spatial light modulator (SLM) or digital micromirror device (DMD). Conical phases with different signs and angles (θ) are applied to the spatial light modulator in order to obtain zero-order Bessel beam, and conical-phased beam is obtained. The said Bessel beam is obtained by Bessel type phase equation (1)

∅(r)=exp[±i2kr tan(θ/2)]=exp(±i2 πr/r₀) (1)

In the formula, θ is a conical angle and the wave vector k is related to wavelength λ by the equation k=2 π/λ. r is the radial coordinate of the beam. r₀ is normalized in terms of pixel numbers. (For example, for an SLM of 20 μm pixel size, r₀=10 pixels corresponds to 10×20=200 μm). For the wavelength λ=1.55 μm, the applied phase on the SLM is equivalent to a conical angle of θ˜0.43°.

At the step of magnifying the conical angle of the beam and then transmitting it onto the focusing lens (105) of the inventive method (100), angle of the conical phased beam is magnified by means of a 4-f system and the beam is transmitted to the focusing lens therefrom. The 4-f system is used for carrying the image between two points by two lenses with a focal length off with a distance of 2 f and for filtering the unwanted SLM-induced frequencies at the middle point of the lenses—in the Fourier plane. A microscope objective lens, a high-NA aspheric lens or another focusing optics are used for the final focusing in the laser writing without mask and moulding. The beam polarization in the final laser-writing beam is converted by using HWP or QWP, or a polarizer which is a combination thereof.

At the step of obtaining micro/nano-structures embedded inside the silicon chip by positioning the beam, that is received from the focusing lens, inside the silicon chip and determining the scanning direction (106) of the inventive method (100), the spatially-modulated laser beam is directed inside a silicon chip placed on a motorized table by focusing and then the lithography process is initiated. The silicon chip is moved by motorized table in accordance with the incident laser direction by controlling the speed and acceleration. Upon the initiation of the lithography process, one-dimensionally (1D)-confined sub-surface micro structures (41Micro), two-dimensionally (2D)-confined sub-surface micro structures (42Micro), one-dimensionally (1D)-confined sub-surface nano-structures that are reduced to 100 nm lithographic dimension (41Nano) and two-dimensionally (2D)-confined sub-surface nano-structures (42Nano) by means of a physical effect called seeding effect of the previous structures to the next structures are obtained. In an embodiment of the invention, the Gaussian beam modulated by the Bessel type phase equation (1) is used. In situ lithography is realized upon the laser affects a single region instead of large volume lithography and the scanning speed is selected to be zero.

In the inventive method (100), Bessel beams are obtained by applying a conical phase to the digital device and equation no. (1) is used during this process. Different orders of Bessel beams and “Modified Bessel beams” can be used as well. The FIG. 2 shows a representative beam profile created by reflecting a Gaussian beam of 4 mm diameters from the SLM with a positive phase sign and r₀=10×20 μm. The magnification factor in the 4-f system is 1.25 to match the aperture. An aspheric lens with f=4.5 mm and NA=0.55 focuses the beam into the silicon chip. The optical simulation based on Fourier propagation is compared with the experimental result (the FIG. 2). The experimental profile confirms the formation of a central core surrounded by concentric rings in the transverse plane, which elongates over a long distance in the optical axis, over the so-called Bessel zone length. These observations are in accordance with the simulation (the FIG. 2).

It is possible to achieve progressively smaller structure sizes inside silicon by using Bessel beams of smaller ro values (smaller ro corresponds to larger conical angles). The lithographic dimensions are reduced to sub-micron scale because of the effective core diameter reduction; that is optical intensity above the modification threshold is appropriately reduced. During the process of writing the laser inside the silicon chip and positioning (106), it is aimed to modify the silicon chip with 1D (41) and 2D (42)-confined structures. As shown in the FIG. 3, the writing process inside the chip (41) starts with the transverse scanning in the silicon chip with respect to the laser propagation direction. The feature size of the fabricated structures are controlled by proper selection of the polarization, the applied phase, the scanning speed and direction, and the power. By using this method (100), as illustrated in the FIG. 4(a), the prior art's limit is broken and the structures (41) in micro (41Micro) and nano (41Nano) scale can be fabricated, by changing the parameter ro in the applied phase or the power control. For these fabrications, the linear polarization parallel to the scanning direction is chosen. When the laser polarization direction is chosen at a different angle, additional control is provided and fabrication of different feature sizes is observed depending on the polarization direction. Scanning electron microscopy (SEM) images of multiple (41Nano) structures, diced from the middle and chemically etched, are shown in the FIG. 4(b).

In order to further decrease the feature size of (41Nano) and keep the fabrication yields high, it was found that reducing the power for the r₀=10 Bessel beam is a powerful method and the fabrication was carried out successfully even in the sub-diffraction regime, as shown in the FIG. 5(a). The histogram in the inset shows the standard deviation of the feature sizes. The SEM image of the periodic uniform sub-diffraction 1D-confined structures (41Nano) is shown in the FIG. 5(b).

Fabrication of 2D-confined micro-structures (42Micro) was carried out by either exposing the sample for a certain amount of time or moving silicon along the laser propagation direction, by a longitudinal scan. However, this does not work for creating nano-scale 2D-confined structures requiring extension of the developed methods.

In order to achieve 2D nano-confinement inside silicon (42Nano), a “seeding” method (the FIG. 3) that exploits the effect of pre-written (41Micro or 41Nano) structures was discovered. The obtained 2-dimensionally confined nano-arrays (42Nano) can be formed within a certain range of the seed (41).

While (42Nano) do not start being formed far away from the (41); once it is formed (in the proximity of a seed), they can easily be elongated along the optical axis, meaning that (42Nano) could be extended throughout the bulk of silicon chip simply by longitudinal scan, including areas without the influence of the seed.

In order to image these sub-surface nano-structures, the silicon is laterally polished and chemically etched. The FIG. 6 confirms the claimed technique. By adjusting the initial position of the Bessel zone inside the silicon chip, using motorized table and adjusting the longitudinal scanning length; (42Nano) structures are extended throughout the entire thickness without damaging either the front or back surface of the silicon wafer. This allows to reach the structures by polishing the sample from either surface and also makes it possible to exploit the array of cylindrically shaped 2D confined nano-structures at a depth where the (41) is absent. These structures can be arranged in arbitrary arrays of 2D-confined building blocks that allow rich architectural designs and large-scale volumetric coverage preserving nano-scale lithographic features. The seeding method can be also used to create 42′Micro structures. The difference of the 42′Micro structures from 42Micro structures is that they use seeding, but the seeding technique is not compulsory for micro-scale fabrication.

With the inventive method (100), the dependence of architecture of (42Nano) structures to laser polarization was discovered. By using the same writing parameters, the (42Nano) structure arrays created with four different polarizations are shown in the FIG. 7. A key observation obtained from this experiment is that the ellipticity and elongation direction of the nano-structures can be controlled with laser polarization. The nano-structures created with linear polarization are asymmetric, confined to a narrow volume and elongate along the polarization direction (the FIG. 7). Further, the feature size in the direction perpendicular to polarization is significantly reduced for linear polarization (350 nm), compared to the feature size of structures created with circular polarization (800 nm) using the same parameter set except polarization. This critical observation also indicates that while the symmetric in-chip nanofabrication require circular polarization, it is possible to venture deeper inside the nano-regime with linear polarization. The lithographic in-chip nanostructures created have the potential to be used in complex architectures and advanced devices.

With the inventive method (100), nano-scale and in-chip lithography with high control and repeatability has become possible by focusing the laser pulses—operating in a wavelength (˜1-5 μm) wherein the silicon chip is transparent—into the chip by patterning with a spatial light modulator. Further, a lithography under 1-μm structure-size was performed in a controlled and repeatable way, at a desired location and depth inside the silicon chip, without damaging the chip surface. The distance between the lithographic structures is also below 1-μm. On the other hand, the in-chip lithography resolution was advanced 10 times and reduced to 100 nm. One-dimensionally and two-dimensionally confined (linear and planar) nano-structures have been fabricated. In addition, three-dimensionally confined (spot) and 100 nm scale structures were observed.

Within these basic concepts; it is possible to develop various embodiments of the inventive “Nano-Scale Lithography Method (100)”; the invention cannot be limited to examples disclosed herein and it is essentially according to claims.

1. A method (100) which enables to fabricate one-dimensionally (linear) and two-dimensionally (planar)-confined micro/nano-structures at a desired position and depth inside a silicon chip, as embedded inside the chip and without damaging the chip surface, by means of spatially-structured laser beams; characterized by the steps of
obtaining laser beam by means of a light source (101);
controlling the power of the light transmitted from the light source (102);
adjusting the beam diameter and polarization (103);
obtaining conical-phase beams by modulating the beam (104);
magnifying the conical angle of the beam and then transmitting it onto the focusing lens (105); and
obtaining micro/nano-structures embedded inside the silicon chip by positioning the beam, that is received from the focusing lens, inside the silicon chip and determining the scanning direction (106).

2. A method (100) according to claim 1; characterized in that at the step of obtaining laser beam by means of a light source (101), the light source used is laser and it emits Gaussian pulses with a 1-30 nanoseconds width and a repetition rate of 1-300 kHz.

3. A method (100) according to claim 1; characterized in that at the step of obtaining laser beam by means of a light source (101), the beam is obtained in the wavelength range wherein the silicon chip is transparent, by means of light source.

4. A method (100) according to claim 3; characterized in that at the step of obtaining laser beam by means of a light source (101), the beam is used in a wavelength of 1.55 μm wherein the silicon chip is transparent.

5. A method (100) according to claim 1; characterized in that at the step of controlling the power of the light transmitted from the light source (102), power of the light transmitted from the light source is controlled by means of a power controller that can be a quarter-wave plate (QWP) and half-wave plate (HWP), neutral density filter, or any power adjusting component.

6. A method (100) according to claim 5; characterized in that at the step of controlling the power of the light transmitted from the light source (102), laser pulse energy is changed for fixed pulse width and repetition rate by means of power controller.

7. A method (100) according to claim 1; characterized in that at the step of adjusting the beam diameter and polarization (103), a telescope system consisting of two lenses or a beam expander is used for adjustment of beam diameter.

8. A method (100) according to claim 7; characterized in that at the step of adjusting the beam diameter and polarization (103), for polarization, a polarizing-beam-splitter (PBS) or wave plate is used to obtain s-polarization, p-polarization.

9. A method (100) according to claim 7; characterized in that at the step of adjusting the beam diameter and polarization (103), for polarization, any linear combination of s- and p-polarizations (circular or elliptical polarization) is used.

10. A method (100) according to claim 1; characterized in that at the step of obtaining conical-phase beams by modulating the beam (104), the beam with adjusted diameter and polarization —namely the Gaussian beam— is transmitted to a physical or virtual digital device which modulates the Gaussian beam.

11. A method (100) according to claim 10 which is configured to enable performing light modulation by applying computer-generated phase profiles, by using a spatial light modulator (SLM) or digital micromirror device (DMD) at the step of obtaining conical-phase beams by modulating the beam (104).

12. A method (100) according to claim 10; characterized in that at the step of obtaining conical-phase beams by modulating the beam (104), conical phases with different signs and angles (θ) are applied to the spatial light modulator in order to obtain zero-order Bessel beam, and conical phased beam is obtained.

13. A method (100) according to claim 12; characterized in that at the step of obtaining conical-phase beams by modulating the beam (104), the Bessel beam is obtained by Bessel type phase equation (1):
∅(r)=exp[±i2kr tan(θ/2)]=exp(±i2 πr/r₀) (1)

14. A method (100) according to claim 1, characterized in that at the step of magnifying the conical angle of the beam and then transmitting it onto the focusing lens (105), angle of the conical phased beam is magnified by means of a 4-f system and the beam is transmitted to the focusing lens therefrom.

15. A method (100) according to claim 14; characterized in that at the step of magnifying the conical angle of the beam and then transmitting it onto the focusing lens (105), a microscope objective lens, a high-NA aspheric lens or another focusing optics are used for the final focusing in the laser writing without mask and moulding.

16. A method (100) according to claim 15; characterized in that at the step of magnifying the conical angle of the beam and then transmitting it onto the focusing lens (105), the beam polarization in the final laser-writing beam is converted by using HWP or QWP, or a polarizer which is a combination thereof

17. A method (100) according to claim 1; characterized in that at the step of obtaining micro/nano-structures embedded inside the silicon chip by positioning the beam, that is received from the focusing lens, inside the silicon chip and determining the scanning direction (106), the spatially-modulated laser beam is directed inside a silicon chip placed on a motorized table by focusing and then the lithography process is initiated.

18. A method (100) according to claim 17; characterized in that at the step of obtaining micro/nano-structures embedded inside the silicon chip by positioning the beam, that is received from the focusing lens, inside the silicon chip and determining the scanning direction (106), the silicon chip is moved by motorized table in accordance with the incident laser direction by controlling the speed and acceleration.

19. A method (100) according to claim 17; characterized in that at the step of obtaining micro/nano-structures embedded inside the silicon chip by positioning the beam, that is received from the focusing lens, inside the silicon chip and determining the scanning direction (106), upon the initiation of the lithography process, one-dimensionally (1D)-confined sub-surface micro structures (41Micro), two-dimensionally (2D)-confined sub-surface micro structures (42Micro), one-dimensionally (1D)-confined sub-surface nano-structures that are reduced to 100 nm lithographic dimension (41Nano) and two-dimensionally (2D)-confined sub-surface nano-structures (42Nano) by means of a physical effect called seeding effect of the previous structures to the next structures are obtained.

20. A method (100) according to claim 1; characterized in that the Gaussian beam modulated by the Bessel type phase equation (1) is used.

21. A method (100) according to claims 17; characterized in that the scanning speed is selected to be zero in order to realize in situ lithography with the laser affecting a single region instead of large volume lithography.
